(19) United States
(12) Patent Application Publication
(10) Pub. No.: US 2026/0039304 A1
(43) Pub. Date: Feb. 5, 2026

(54) INTEGRATOR OPERATING BASED ON VARIABLE CURRENT

(71) Applicant: Realtek Semiconductor Corp., HsinChu (TW)

(72) Inventor: Chia-Ling Chang, HsinChu (TW)

(73) Assignee: Realtek Semiconductor Corp., HsinChu (TW)

(21) Appl. No.: 18/793,959

(22) Filed: Aug. 5, 2024

(30) Foreign Application Priority Data
Aug. 10, 2023 (TW) 112130110

(51) Int. Cl. H03M 1/00; H03F 3/45

(52) U.S. Cl. CPC H03M 1/002; H03F 3/45076

(57) ABSTRACT

An integrator operating based on a variable current is provided. The integrator includes an operational amplifier, wherein the operational amplifier includes an amplifying stage circuit and a bias circuit. The amplifying stage circuit is configured to provide an amplification gain. The bias circuit is coupled to the amplifying stage circuit and is configured to control a bias condition of the amplifying stage circuit according to the variable current output from a variable current source. In a sampling phase of the integrator, the variable current source switches the variable current to a sampling current value. In an integration phase of the integrator, the variable current source switches the variable current to an integration current value. More particularly, the sampling current value is less than the integration current value.

### BACKGROUND OF THE INVENTION

### 1. Field of the Invention

The present invention is related to integrators, and more particularly, to an integrator operating based on a variable current.

### 2. Description of the Prior Art

A typical sigma-delta analog-to-digital converter (ADC) comprises multiple components such as a loop filter, a quantizer, a digital-to-analog converter (DAC) and a decimation filter, and performs a high-resolution analog-to-digital conversion on signals (e.g. audio signals) which demand high resolution. The loop filter therein is typically formed by power consuming analog circuits (e.g. integrators comprising operational amplifiers). For low power applications, reducing power consumption of the loop filter (e.g. the integrators therein) is an important issue.

Thus, there is a need for a novel current bias architecture for an integrator which can reduce overall power consumption.

### SUMMARY OF THE INVENTION

An objective of the present invention is to provide an integrator which operates based on a variable current, which can reduce power consumption introduced in a discrete-time sigma-delta analog-to-digital conversion operation.

At least one embodiment of the present invention provides an integrator operating based on a variable current. The integrator comprises an operational amplifier, where the operational amplifier comprises an amplifying stage circuit and a bias circuit coupled to the amplifying stage circuit. The amplifying stage circuit is configured to provide an amplification gain, and the bias circuit is configured to control a bias condition of the amplifying stage circuit according to the variable current output from a variable current source. In a sampling phase of the integrator, the variable current source switches the variable current to a sampling current value. In an integration phase of the integrator, the variable current source switches the variable current to an integration current value. More particularly, the sampling current value is less than the integration current value.

The integrator provided by the embodiment of the present invention can operate based on corresponding current values in the sampling phase and the integration phase, respectively. More particularly, a lower current value is utilized in the sampling phase which demands lower speed requirement, and a greater current value is utilized in the integration phase which demands higher speed requirement. Thus, the present invention can reduce an overall power consumption without affecting original operations of the integrator.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an integrator according to an embodiment of the present invention.

FIG. 2 is a diagram illustrating control clocks associated with the integrator shown in FIG. 1 according to an embodiment of the present invention.

FIG. 3 is a diagram illustrating an operational amplifier within the integrator shown in FIG. 1 according to an embodiment of the present invention.

FIG. 4 is a diagram illustrating implementation of a variable current source within the operational amplifier shown in FIG. 3 according to an embodiment of the present invention.

FIG. 5 is a diagram illustrating implementation of a variable current source within the operational amplifier shown in FIG. 3 according to another embodiment of the present invention.

FIG. 6 is a diagram illustrating implementation of a variable current source within the operational amplifier shown in FIG. 3 according to yet another embodiment of the present invention.

### DETAILED DESCRIPTION

FIG. 1 is a diagram illustrating an integrator such as a switched capacitor (SC) integrator 10 according to an embodiment of the present invention. As shown in FIG. 1, the SC integrator 10 may comprise an operational amplifier 100, where A₀ may represent a gain of the operational amplifier 100. The SC integrator 10 may further comprise switches S1, S2, S3 and S4 and capacitors C1 and C2. The switch S1 is coupled between an input terminal of the SC integrator 10 and a first terminal (e.g. a left-side terminal thereof) of the capacitor C1. The switch S2 is coupled between a second terminal (e.g. a right-side terminal thereof) of the capacitor C1 and a negative input terminal (labeled “−” in FIG. 1 for brevity) of the operational amplifier 100. The switch S3 is coupled between the second terminal of the capacitor C1 and a reference voltage terminal (e.g. a ground voltage terminal). The switch S4 is coupled between the first terminal of the capacitor C1 and the reference voltage terminal. A positive input terminal (labeled “+” in FIG. 1 for brevity) of the operational amplifier 100 is coupled to the reference voltage terminal, and the capacitor C2 is coupled between an output terminal and the negative input terminal of the operational amplifier 100. The input terminal of the SC integrator 10 may receive an input signal VIN and perform integration on the input signal according to a ratio of the capacitors C1 and C1, in order to generate an output signal VOUT on an output terminal of the SC integrator 10 (e.g. the output terminal of the operational amplifier 100). It should be noted that the SC integrator 10 shown in FIG. 1 shows a single-ended circuit architecture for illustrative purposes only, and is not meant to be a limitation of the present invention. Those skilled in this art should understand a corresponding differential circuit architecture according to the architecture shown in FIG. 1 and the above descriptions; this architecture will not be described in detail here for brevity.

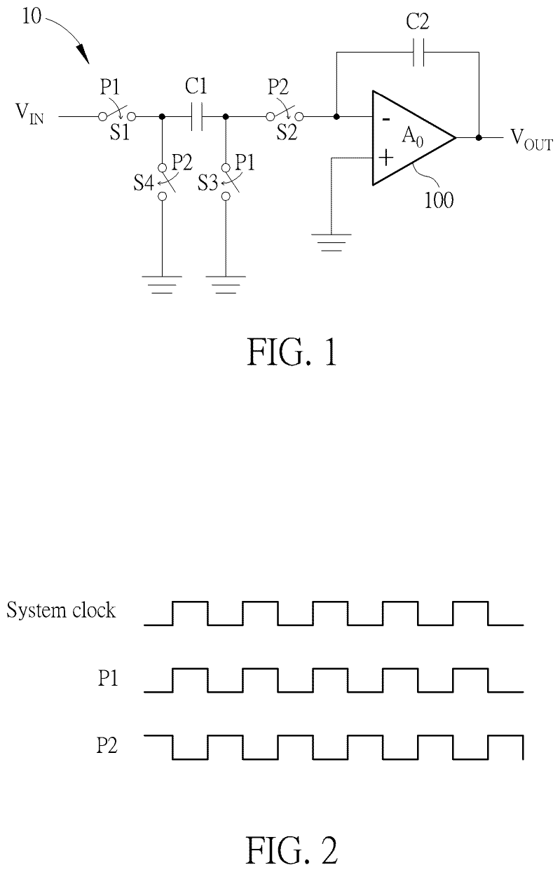

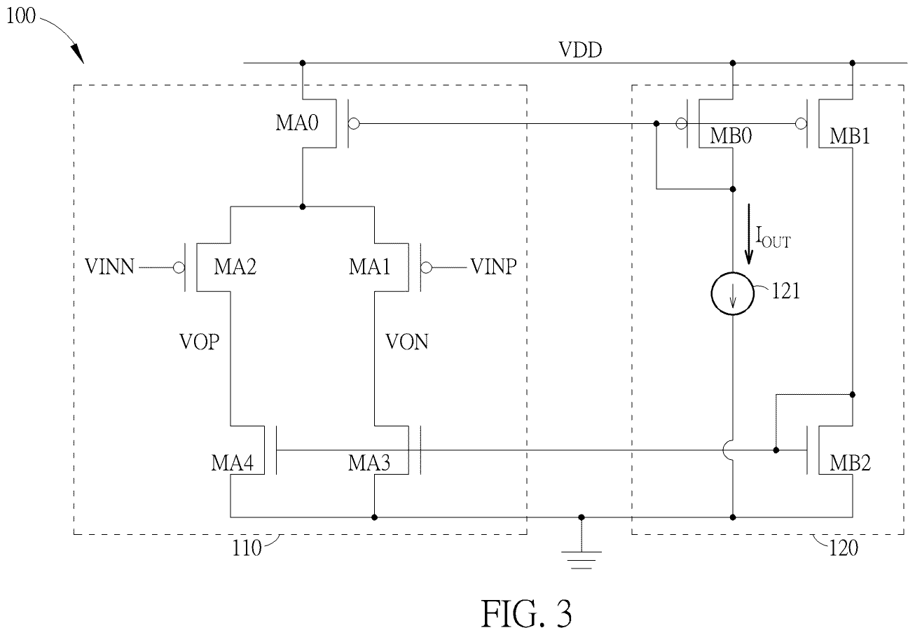

In this embodiment, the switches S1 and S3 being turned on (e.g. made conductive) is controlled by a control clock P1, and the switches S2 and S4 being turned on is controlled by a control clock P2. FIG. 2 is a diagram illustrating control clocks associated with the SC integrator 10 shown in FIG. 1 according to an embodiment of the present invention, where the control clocks P1 and P2 may be generated based on a system clock by a non-overlapping clock generator. Periods of the control clock P1 at a high level (e.g. having a logic value “1”) may represent periods of the switches S1 and S3 being turned on, and periods of the control clock P1 at a low level (e.g. having a logic value “0”) may represent periods of the switches S1 and S3 being turned off. Similarly, periods of the control clock P2 at the high level (e.g. having the logic value “1”) may represent periods of the switches S2 and S4 being turned on, and periods of the control clock P2 at the low level (e.g. having the logic value “0”) may represent periods of the switches S2 and S4 being turned off.

In this embodiment, each of the periods of the control clock at the high level may be taken as a sampling phase of the SC integrator 10, and each of the periods of the control clock P2 at the high level may be taken as an integration phase of the SC integrator 10. In the sampling phase (e.g. in a period of the sampling phase), the switches S1 and S3 are turned on and the switches S2 and S4 are turned off, and the input signal VIN may be sampled to the capacitor C1, where the operational amplifier 100 is configured to maintain a level of the output signal VOUT in the sampling phase only, and does not substantially charge/discharge the capacitor C2. In the integration phase (e.g. in a period of the integration phase), the switches S2 and S4 are turned on and the switches S1 and S3 are turned off, and charges on the capacitor C1 may be transferred to the capacitor C2 for performing an integration operation, where the operational amplifier 100 may drive the level of the output signal VOUT to a result of the integration operation based on the input signal VIN and the ratio of the capacitors C2 and C1. Based on the above behavior, operation speed requirement of the operational amplifier 100 in the sampling phase is less than the operation speed requirement in the integration phase. Thus, the present invention provides different bias currents to the operational amplifier 100 in the sampling phase and the integration phase, respectively, to effectively reduce power consumption of the operational amplifier 100 without greatly affecting an overall performance.

FIG. 3 is a diagram illustrating the operational amplifier 100 within the SC integrator 10 shown in FIG. 1 according to an embodiment of the present invention, where the operational amplifier 100 operates based on power of a supply voltage terminal VDD, in order to amplify a differential input signal between input terminals VINP and VINN to generate a differential output signal between output terminals VOP and VON. As shown in FIG. 1, the operational amplifier 100 may comprise an amplifying stage circuit 110 and a bias circuit 120, where the bias circuit 120 is coupled to the amplifying stage circuit 110. In this embodiment, the amplifying stage circuit 110 is configured to provide an amplification gain (e.g. A₀), and the bias circuit 120 is configured to control a bias condition of the amplifying stage circuit 110 according to a variable current I_{OUT} output from a variable current source 121. For example, in the sampling phase of the SC integrator 10, the variable current source 121 may switch the variable current I_{OUT} to a sampling current value. In the integration phase of the SC integrator 10, the variable current source 121 may switch the variable current I_{OUT} to an integration current value. More particularly, the sampling current value is less than the integration current value.

In this embodiment, the amplifying stage circuit 110 may be implemented by a single-stage amplifier, where the amplifying stage circuit 110 may comprise multiple transistors such as P-type transistors MA0, MA1 and MA2 and N-type transistors MA3 and MA4. In addition, the bias circuit 120 may comprise the variable current source 121 and at least one current mirror circuit, where the at least one current mirror circuit is coupled to the variable current source 121 and the amplifying stage circuit 110, and is configured to generate one or more bias voltages according to the variable current I_{OUT}, to control the bias condition of the amplifying stage circuit 110. In this embodiment, the at least one current mirror circuit may comprise a P-type transistor MB0, where the P-type transistor MB0 may generate a bias voltage of the P-type transistor MA0 (e.g. a gate voltage of the P-type transistor MA0) according to the variable current I_{OUT}, to make a current output from the P-type transistor MA0 (i.e. a bias current of the amplifying stage circuit 110) be modified in response to modification of the variable current I_{OUT}. In addition, bias voltages of the N-type transistors MA3 and MA4 (e.g. gate voltages of the N-type transistors MA3 and MA4) may be controlled via a P-type transistor MB1 and an N-type transistor MB2. As those skilled in this art should understand how to apply the change in the variable current I_{OUT} to the bias voltages of the amplifying stage circuit 110 to thereby control speed (e.g. an operation bandwidth) and power consumption of the operational amplifier 100 through operations of the current mirror according to the architecture shown in FIG. 3, related details are omitted here for brevity. In addition, the amplifying stage circuit 110 of the embodiment of FIG. 3 is for illustrative purposes only, and is not meant to be a limitation of the present invention. For example, the amplifying stage circuit 110 may be implemented by other architecture such as a multi-stage amplifier and a cascode amplifier. Those skilled in this art should understand how to implement the bias circuit 120 corresponding to these different architectures of the amplifying stage circuit 110 according to the above descriptions and the architecture shown in FIG. 3, and related details are omitted here for brevity.

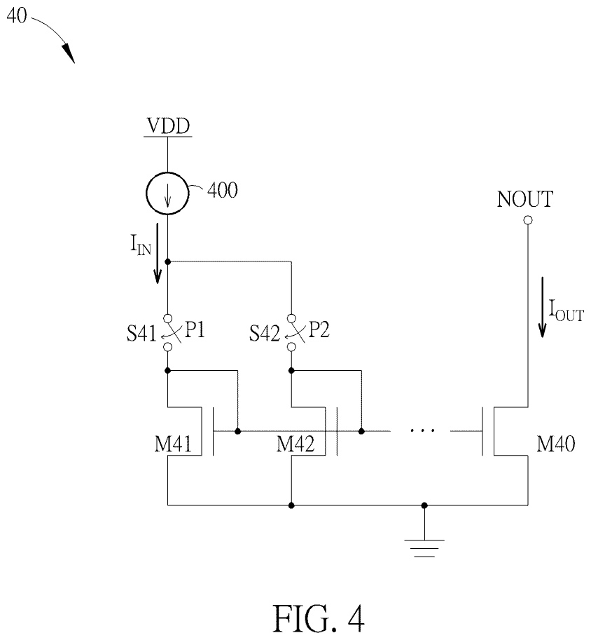

FIG. 4 is a diagram illustrating implementation of the variable current source 121 (e.g. a variable current source 40) within the operational amplifier 100 shown in FIG. 3 according to an embodiment of the present invention. As shown in FIG. 4, the variable current source 40 may comprise a constant current source 400, an output circuit such as an N-type transistor M40, a first current mirror circuit such as an N-type transistor M41, and a second current mirror circuit such as an N-type transistor M42. In this embodiment, the constant current source 400 is configured to output a constant current I_{IN}, and the N-type transistor M40 is configured to output the variable current I_{OUT}. For example, the N-type transistor M40 is coupled between an output terminal NOUT and the reference voltage terminal (e.g. the ground voltage terminal), where the output terminal NOUT is coupled to the P-type transistor MB0 shown in FIG. 3, but the present invention is not limited thereto. In addition, the N-type transistor M41 is configured to receive the constant current I_{IN} the sampling phase to control the N-type transistor M40 (e.g. controlling a gate voltage of the N-type transistor M40) according to a first predetermined ratio (e.g. a dimension ratio of the N-type transistors M40 and M41) and the constant current I_{IN}, in order to make the variable current I_{OUT} be switched to the sampling current value (e.g. a result of multiplying the constant current I_{IN} by the first predetermined ratio). The N-type transistor M42 is configured to receive the constant current I_{IN} the integration phase to control the N-type transistor M40 (e.g. controlling the gate voltage of the N-type transistor M40) according to a second predetermined ratio and the constant current I_{IN}, in order to make the variable current I_{OUT} be switched to the integration current value (e.g. a result of multiplying the constant current I_{IN} by the second predetermined ratio).

In this embodiment, the variable current source 40 may further comprise switches S41 and S42, where the switch S41 is coupled between the N-type transistor M41 and the constant current source 400, and the switch S42 is coupled between the N-type transistor M42 and the constant current source 400. More particularly, the switch S41 being turned on is controlled by the control clock P1, and the switch S42 being turned on is controlled by the control clock P2. Thus, the switch S41 is configured to be turned on in the sampling phase to couple the N-type transistor M41 to the constant current source 400, in order to switch the variable current I_{OUT} to the sampling current value. The switch S42 is configured to be turned on in the integration phase to couple the N-type transistor M42 to the constant current source 400, in order to switch the variable current I_{OUT} to the integration current value.

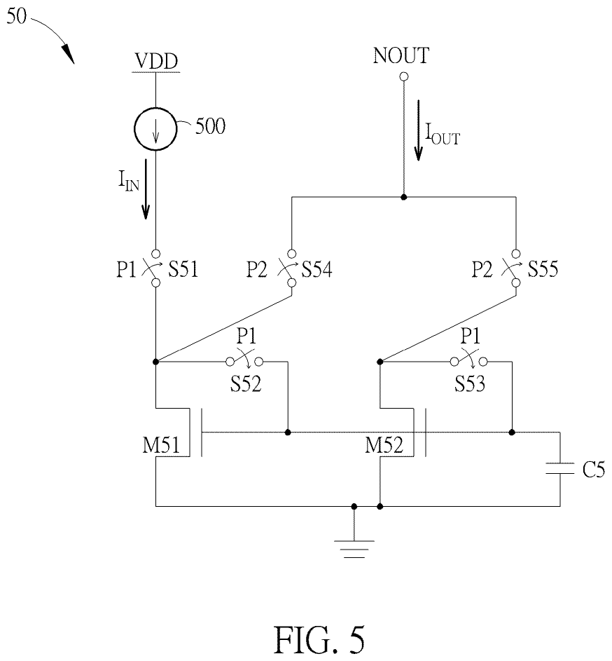

FIG. 5 is a diagram illustrating implementation of the variable current source 121 (e.g. the variable current source 50) within the operational amplifier 100 shown in FIG. 3 according to another embodiment of the present invention. As shown in FIG. 5, the variable current source 50 may comprise a constant current source 500, at least one transistor such as N-type transistors M51 and M52, and a capacitor C5. In this embodiment, the constant current source 500 is configured to output the constant current IN. In addition, the N-type transistors M51 and M52 are configured to store a control voltage on the capacitor C5 according to the constant current I_{IN} in the sampling phase, and the N-type transistors M51 and M52 are configured to generate the integration current value according to the control voltage in the integration phase.

In this embodiment, the variable current source 50 may further comprise switches S51, S52, S53, S54 and S55, where the switch S51 is coupled between the N-type transistor M51 and the constant current source 500, the switch S52 is coupled between a gate electrode and a drain electrode of the N-type transistor M51, the switch S53 is coupled between a gate electrode and a drain electrode of the N-type transistor M52, the switch S54 is coupled between the N-type transistor M51 and the output terminal NOUT, and the switch S55 is coupled between the N-type transistor M52 and the output terminal NOUT. More particularly, each of the switches S51, S52 and S53 being turned on is controlled by the control clock P1, and each of the switches S54 and S55 being turned on is controlled by the control clock P2. Thus, the switches S51, S52 and S53 are configured to be turned on in the sampling phase to make the N-type transistors M51 and M52 receive the constant current I_{IN} via the switch S51, where the switches S52 and S53 are turned on in the sampling phase to make the N-type transistors M51 and M52 store the control voltage on the capacitor C5 according to the constant current I_{IN}. For example, the capacitor C5 is coupled to gate electrodes of the N-type transistors M51 and M52. Thus, when the N-type transistors M51 and M52 generate a gate voltage thereof in response to the constant current I_{IN}, this gate voltage may be taken as the control voltage and is stored on the capacitor C5. In addition, the switches S54 and S55 are configured to be turned on in the integration phase to make the N-type transistors M51 and M52 output the variable current I_{OUT} having the integration current value to the output terminal Nour according to the control voltage (e.g. the gate voltage generated in response to the constant current I_{IN} by the N-type transistors M51 and M52).

It should be noted that, as the switches S54 and S55 are turned off in the sampling phase, the variable current I_{OUT} is switched to zero in the sampling phase (i.e. the sampling current is zero). In comparison with the variable current source 40 shown in FIG. 4, the variable current source 50 shown in FIG. 5 does not have a static current continuously flowing out from the output terminal NOUT. Thus, an overall power consumption can be further reduced.

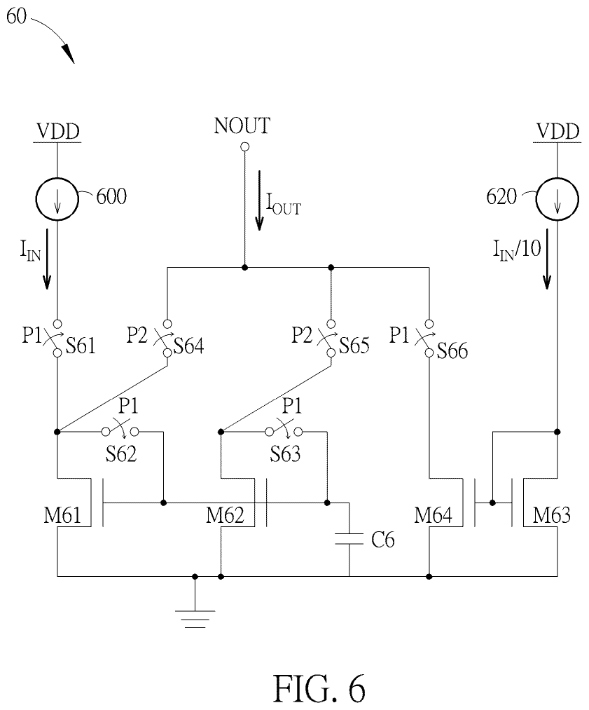

When an operation speed of the SC integrator 10 is increased (e.g. when a frequency of the system clock is increased), the operation of switching the variable current I_{OUT} to zero in the sampling phase may be unable to ensure stability of an overall circuit when iteratively switching between the sampling phase and the integration phase. Based on high speed operation requirements, the variable current source 50 may be further improved as illustrated by a variable current source 60 shown in FIG. 6, where FIG. 6 is a diagram illustrating implementation of the variable current source 121 (e.g. the variable current source 60) within the operational amplifier 100 shown in FIG. 3 according to yet another embodiment of the present invention.

As shown in FIG. 6, the variable current source 60 may comprise constant current sources 600 and 620, at least one transistor such as N-type transistors M61 and M62, a current mirror circuit such as an N-type transistor M63, an output circuit such as an N-type transistor M64, and a capacitor C6. In this embodiment, the constant current source 600 is configured to output a first constant current such as the constant current I_{IN}, and the constant current source 620 is configured to output a second constant current such as one tenth of the constant current I_{IN} (referred to as “the constant current I_{IN}/10”). It should be noted that the second constant current is preferably less than the first constant current, but the present invention is not limited thereto. In addition, a ratio of the first constant current and the second constant current mentioned above is for illustrative purposes only, and is not meant to be a limitation of the present invention; the ratio of the first constant current and the second constant current may vary in response to the operation speed and power consumption requirements. In addition, the N-type transistors M61 and M62 are configured to store a control voltage (e.g. a gate voltage generated according to the constant current by the N-type transistors M61 and M62) on the capacitor C6 according to the constant current I_{IN} in the sampling phase, and the N-type transistors M61 and M62 are configured to generate the integration current value according to the control voltage in the integration phase. More particularly, the N-type transistor M63 is configured to receive the constant current I_{IN}/10 from the constant current source 620, to generate the sampling current value according to a predetermined ratio (e.g. a dimension ratio of the N-type transistors M63 and M64) and the constant current II/10 (e.g. by multiplying the constant current II/10 by the predetermined ratio), and the N-type transistor M64 is configured to output the variable current I_{OUT} having the sampling current value in the sampling phase.

In this embodiment, the variable current source 60 may further comprise switches S61, S62, S63, S64, S65 and S66, where the switch S61 is coupled between the N-type transistor M61 and the constant current source 600, the switch S62 is coupled between a gate electrode and a drain electrode of the N-type transistor M61, the switch S63 is coupled between a gate electrode and a drain electrode of the N-type transistor M62, the switch S64 is coupled between the N-type transistor M61 and the output terminal NOUT, the switch S65 is coupled between the N-type transistor M62 and the output terminal NOUT, and the switch S66 is coupled between the N-type transistor M64 and the output terminal NOUT. More particularly, each of the switches S61, S62, S63 and S66 being turned on is controlled by the control clock P1, and each of the switches S64 and S65 being turned on is controlled by the control clock P2. Thus, the switches S61, S62 and S63 are configured to be turned on in the sampling phase to make the N-type transistors M61 and M62 receive the constant current I_{IN} via the switch S61, where the switches S62 and S63 are turned on in the sampling phase to make the N-type transistors M61 and M62 store the control voltage on the capacitor C6 according to the constant current I_{IN}. For example, the capacitor C6 is coupled to gate electrodes of the N-type transistors M61 and M62. Thus, when the N-type transistors M61 and M62 generate a gate voltage thereof in response to the constant current I_{IN}, this gate voltage may be taken as the control voltage and be stored on the capacitor C6. In addition, the switches S64 and S65 are configured to be turned on in the integration phase, to make the N-type transistors M61 and M62 output the variable current I_{OUT} having the integration current value to the output terminal NOUT according to the control voltage (e.g. the gate voltage generated in response to the constant current I_{IN} by the N-type transistors M61 and M62). It should be noted that the switch S66 is configured to be turned on in the sampling phase, to make the N-type transistor M64 output the variable current I_{OUT} having the sampling current value to the output terminal via the switch S66. In comparison with the embodiment of FIG. 5, as the variable current source 60 utilizes the N-type transistor M64 to output the variable current I_{OUT} in the sampling phase, a current value (i.e. the sampling current value) of the variable current I_{OUT} in the sampling phase is non-zero. Under this architecture, a static current continuously flowing out from the output terminal NOUT may be controlled within an allowable range, and the variable current I_{OUT} in the sampling phase will not be too low, thereby ensuring that the SC integrator 10 can properly operate when the frequency of the system clock is increased.

In some embodiments, the aforementioned integration current value can be switchable. For example, the integration current value may comprise a first integration current value and a second integration current value. When the SC integrator 10 operates at a first frequency, the variable current source 121 may switch the variable current I_{OUT} to the first integration current value in the integration phase. When the SC integrator 10 operates at a second frequency, the variable current source 121 may switch the variable current I_{OUT} to the second integration current value in the integration phase. More particularly, when the second frequency is greater than the first frequency, the second integration current value may be greater than the first integration current value, and the first integration current value may be greater than the sampling current value. Thus, when the SC integrator 10 operates at the first frequency, the variable current I_{OUT} may be switched between the sampling current value and the first integration current value in response to switching between the sampling phase and the integration phase. When the SC integrator 10 operates at the second frequency, the variable current I_{OUT} may be switched between the sampling current value and the second integration current value in response to switching between the sampling phase and the integration phase.

The design of a switchable integration current value as mentioned above may be applied in any of the architectures shown in FIG. 4 to FIG. 6. Those skilled in this art should understand how to add corresponding current branches and/or switch control to any of the architectures shown in FIG. 4 to FIG. 6 for implementing the architecture with multiple integration current values according to descriptions. Related details are omitted here for brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrator operating based on a variable current, comprising:
an operational amplifier, comprising:
an amplifying stage circuit, configured to provide an amplification gain; and
a bias circuit, coupled to the amplifying stage circuit, configured to control a bias condition of the amplifying stage circuit according to the variable current output from a variable current source;
wherein:
in a sampling phase of the integrator, the variable current source switches the variable current to a sampling current value;
in an integration phase of the integrator, the variable current source switches the variable current to an integration current value; and
the sampling current value is less than the integration current value.

2. The integrator of claim 1, wherein the bias circuit comprises the variable current source, and further comprises:
at least one current mirror circuit, coupled to the variable current source and the amplifying stage circuit, configured to generate one or more bias voltages according to the variable current, to control the bias condition of the amplifying stage circuit.

3. The integrator of claim 1, wherein the variable current source comprises:
a constant current source, configured to output a constant current;
an output circuit, configured to output the variable current;
a first current mirror circuit, configured to receive the constant current in the sampling phase to control the output circuit according to a first predetermined ratio and the constant current, in order to make the variable current be switched to the sampling current value; and
a second current mirror circuit, configured to receive the constant current in the integration phase to control the output circuit according to a second predetermined ratio and the constant current, in order to make the variable current be switched to the integration current value.

4. The integrator of claim 3, wherein the variable current source further comprises:
a first switch, coupled between the first current mirror circuit and the constant current source, configured to be turned on in the sampling phase to couple the first current mirror circuit to the constant current source; and
a second switch, coupled between the second current mirror circuit and the constant current source, configured to be turned on in the integration phase to couple the second current mirror circuit to the constant current source.

5. The integrator of claim 1, wherein the variable current source comprises:
a constant current source, configured to output a constant current; and
at least one transistor, wherein the at least one transistor is configured to store a control voltage on a capacitor according to the constant current in the sampling phase, and the at least one transistor is configured to generate the integration current value according to the control voltage in the integration phase.

6. The integrator of claim 5, wherein the variable current source further comprises:
a first switch, coupled between the at least one transistor and the constant current source, configured to be turned on in the sampling phase to make the at least one transistor receive the constant current via the first switch;
a second switch, coupled between a gate electrode and a drain electrode of the at least one transistor, configured to be turned on in the sampling phase to make the at least one transistor store the control voltage on the capacitor according to the constant current, wherein the capacitor is coupled to the gate electrode of the at least one transistor; and
at least one third switch, coupled between the at least one transistor and an output terminal, configured to be turned on in the integration phase to make the at least one transistor output the variable current having the integration current value to the output terminal according to the control voltage.

7. The integrator of claim 1, wherein the variable current source comprises:
a first constant current source, configured to output a first constant current;
at least one transistor, wherein the at least one transistor is configured to store a control voltage on a capacitor according to the first constant current in the sampling phase, and the at least one transistor is configured to generate the integration current value according to the control voltage in the integration phase;
a second constant current source, configured to output a second constant current;
an output circuit, configured to output the variable current having the sampling current value in the sampling phase; and
a current mirror circuit, configured to receive the first constant current to control the output circuit to generate the sampling current value according to a predetermined ratio and the second constant current.

8. The integrator of claim 7, wherein the variable current source further comprises:
a first switch, coupled between the at least one transistor and the first constant current source, configured to be turned on in the sampling phase to make the at least one transistor receive the first constant current via the first switch;
at least one second switch, coupled to a gate electrode and a drain electrode of the at least one transistor, configured to be turned on in the sampling phase to make the at least one transistor store the control voltage on the capacitor according to the first constant current, wherein the capacitor is coupled to the gate electrode of the at least one transistor;
at least one third switch, coupled between the at least one transistor and an output terminal, configured to be turned on in the integration phase to make the at least one transistor output the variable current having the integration current value to the output terminal according to the control voltage; and
a fourth switch, coupled between the output circuit and the output terminal, configured to be turned on in the sampling phase to make the output circuit output the variable current having the sampling current value via the fourth switch.

9. The integrator of claim 1, wherein the integration current value comprises a first integration current value and a second integration current value; when the integrator operates at a first frequency, the variable current source switches the variable current to the first integration current value in the integration phase; and when the integrator operates at a second frequency, the variable current source switches the variable current to the second integration current value in the integration phase.

10. The integrator of claim 9, wherein the second frequency is greater than the first frequency, the second integration current value is greater than the first integration current value, and the first integration current value is greater than the sampling current value.
